(19) United States
(12) Patent Application Publication
(10) Pub. No.: US 2024/0097072 A1
(43) Pub. Date: Mar. 21, 2024

(54) STRUCTURE AND METHOD FOR FORMING OHMIC CONTACTS TO N FACE BULK GAN SUBSTRATE

(71) Applicant: PALO ALTO RESEARCH CENTER INCORPORATED, Palo Alto, CA (US)

(72) Inventors: Max Batres, Palo Alto, CA (US); Thomas Wunderer, Palo Alto, CA (US)

(21) Appl. No.: 17/941,192

(22) Filed: Sep. 9, 2022

(51) Int. Cl. H01L 33/32; H01L 21/02

(52) U.S. Cl. CPC H01L 33/32; H01L 21/02013; H01L 21/02019; H01L 21/0254

(57) ABSTRACT

A semiconductor device is formed on a bulk substrate of n-type GaN. The semiconductor device has a material layer grown on the bulk substrate. A first surface of the bulk substrate facing away from the material layer is mechanically roughened and a negative electrical contact is formed on the roughened surface using a low work function metal.

### SUMMARY

The present disclosure is directed to a structure and method for forming ohmic contacts to nitrogen face bulk GaN substrate. In one embodiment, a method involves mechanically roughening a first surface of a bulk substrate of n-type GaN such that the first surface is not predominantly composed of (0001̅) oriented crystal planes. A negative electrical contact is formed on the roughened surface using a low work function metal. A semiconductor device is formed on a second surface of the bulk substrate facing away from the first surface. The semiconductor device includes an epitaxial layer grown on the second surface and a positive electrical contact formed in contact with the epitaxial layer.

In another embodiment, a method involves forming a semiconductor device on a bulk substrate of n-type GaN. The semiconductor device includes an epitaxial layer grown on the bulk substrate and a positive electrical contact formed in contact with the epitaxial layer. A first surface of the bulk substrate facing away from the positive electrical contact is mechanically roughened to break molecular bonds at the surface resulting in an increase in electronic states. A negative electrical contact is formed on the roughened surface using a low work function metal.

These and other features and aspects of various embodiments may be understood in view of the following detailed discussion and accompanying drawings.

### BRIEF DESCRIPTION OF THE DRAWINGS

The discussion below makes reference to the following figures, wherein the same reference number may be used to identify the similar/same component in multiple figures.

FIG. 1 is a diagram of a device manufactured according to example embodiments;

FIGS. 2-5 are diagrams of processing steps of a method according to an example embodiment;

FIG. 6 is a graph of experimental results evaluating different processing options in a method according to an example embodiment; and

FIGS. 7 and 8 are flowcharts of methods according to example embodiments.

### DETAILED DESCRIPTION

The present disclosure is generally related to manufacturing of electronic devices on crystalline wafers. For example, crystalline group III and nitrogen alloy (III-N) semiconductor material such as GaN can be used for creating a wide variety of solid state devices, such as transistors, diodes, light-emitting diodes (LEDs), lasers, etc. In some cases, the III-N material can be grown on a growth template or substrate such as sapphire or silicon. Under the proper growth conditions, the III-N material can achieve epitaxial growth, in which the added material has a highly regular crystalline structure. When forming a device, in most cases subsequent layers are added with different material compositions to have the electrical and/or optical characteristics desired for the device.

While many device heterostructures are commonly grown on growth templates or foreign substrates (e.g., sapphire, silicon, GaAs, etc.), the use of native GaN substrates can provide distinct benefits. In most cases, GaN substrates can offer a higher material quality, i.e., lower threading dislocation density, thus, improving the device performance and/or life time.

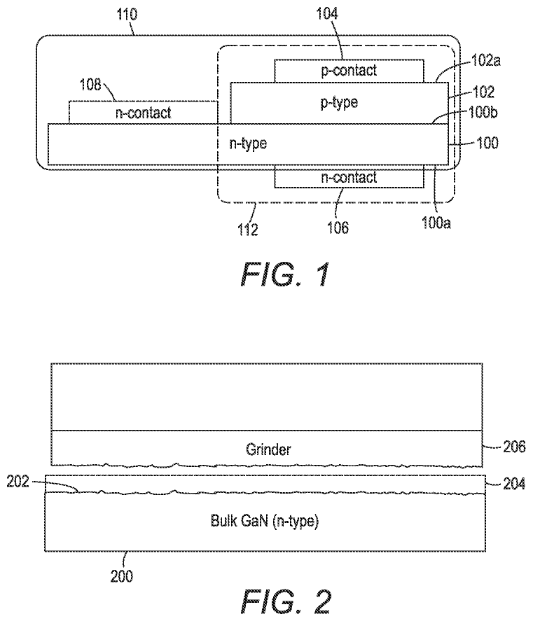

Bulk GaN as a substrate material for epitaxy has found increasing uses in wide band-gap semiconductor devices. At present, these devices include optical emitters, such as lasers and LEDs, and power electronics. In many practical applications, it is desired to form electrical contacts on the device ‘vertically’, that is current can flow from a ‘top’-side contact to the opposing ‘bottom’-side contact or vice versa. This means the ‘top’-side contact would be formed on the gallium-terminated side of the III-N crystal and the ‘bottom’-side contact would be placed on the nitrogen-terminated side. In FIG. 1 a diagram illustrates an example of a vertical contact arrangement of a device according to an example embodiment. A bottom layer 100 includes n-type material, and a top layer 102 of p-type is epitaxially formed on the bottom layer 100. Note that the illustration is intended to illustrate example device geometries and there may be additional layers between the bottom and top layers 100, 102 in a practical device.

As the group III-nitrides are nearly always grown such that the p-doped material is formed last (top), the p-contacts 104 are typically applied to the epitaxially grown surface 102a of the top layer 102 and the n-contact 106 is made to the substrate material backside surface 100a. In the case of bulk GaN, it is well established that the nitrogen face (N face), which forms the bottom or backside surface 100a, behaves very differently from the gallium face (Ga face) 100b. While an ohmic contact 104 can be readily formed to the Ga face, the same is not true of the N face. This inability to form a low resistance electrical contact results in increased operating voltage of the final device, and decreased efficiency or other problems.

One strategy to mitigate the poor electrical contact is to increase the n-type doping levels in the material to be contacted. This can be readily done for epitaxially grown material, and N face ohmic contacts can be made to GaN that is epitaxially grown. This is common for substrate removed devices including widely adopted LED emitter designs. On the other hand, for GaN single crystals formed by bulk growth methods, there are significant limitations on dopant additions during the crystal growth process. For various reasons it is difficult to achieve high doping levels in bulk material. For devices where an ohmic contact (negative contact or n-contact 106) is required to a surface that is both N face and bulk GaN, contacts that are reliably ohmic are difficult to produce, in part due to this comparably low n-type doping level. The typical result is a Schottky or high resistance contact that results in an increased operation voltages of the finished device.

In some cases, the poor N face contact can be avoided altogether by employing a ‘lateral contact’ configuration, where both n and p contacts are made to the Ga face (top) surface. This is shown in FIG. 1 by alternate lateral n-contact 108. However, there are several cases where such a configuration has significant disadvantages, particularly for high power operations. Laser diode devices are one such case.

First, a laterally contacted laser diode design can suffer from increased resistance, as a current density gradient will exist, forcing a higher current from a smaller area resulting in increased voltage. Second, lateral designs suffer from ‘current crowding’, where non-uniform carrier injection causes a gradient in carriers across the active region which can lead to decreased device performance. Third, thermal conductivity is decreased in lateral designs, as heat, the majority of which is generated in the active region adjacent the positive contact 104, can only escape through the p metal layer which is electrically and thermally isolated from the n metal contact 108, limiting the heat dissipation. Finally, a lateral device is by necessity a significantly larger area device (illustrated by box 110) than a vertical device which can accommodate a bottom contact without increasing the area defined by the top contact and active region (illustrated by box 112).

Another approach to deal with poor N face contacts on bulk wafers is to build a vertical device but have a very large area contact on the N face surface (e.g., by increasing the size of the illustrated n-contact), which mitigates the overall series resistance. However, this also increases the size of the individual devices, thus having similar disadvantages to that of a lateral contact. The smaller area of a vertical devices equates to increased wafer yield (e.g., by a factor of two or more). Incidentally, LED devices on bulk GaN have similar considerations to the typical laser device, and the same constraints are likely to apply.

Known methods for producing ohmic contacts to N face bulk GaN involve the use of a laser treatment process whereby one or more laser scribes are formed on the N face surface, upon which a contact is fabricated. Though explanations for the mechanism differ, this method is claimed to work. Nevertheless, this adds an expensive and laborious additional step to the fabrication process.

The disclosed embodiments address the above-described issues in forming contacts on bulk GaN, and may be applicable to other materials, e.g., AlN and other III-N materials. In one or more embodiments, a contact design and fabrication method produces an ohmic contact to negative face bulk GaN substrates, in which the negative ohmic contact has a size similar to that of one or more ohmic contacts on an opposing face of the same device (e.g., a positive contact on a positive face). In FIGS. 2-5, diagrams illustrate a method according to an example embodiment.

A bulk GaN wafer 200 is provided as a base for building devices using known wafer processes, e.g., deposition, photolithographic etching, epitaxial growth, etc. Epitaxial growth, which occurs at ˜1100C for typical GaN growth, can be regarded analogous to a high temperature anneal in same cases. Hence a typical N face GaN surface will have seen a high temperature anneal before n contact deposition. A wafer grind (fixed abrasive) process (as represented by grinder 206), lapping, or other similar thinning creates a first surface 202 that may be characterized by a multiplicity of exposed planes, as distinct from a smooth surface consisting exclusively or predominantly of the N face of the GaN crystal, which is a (0001̅) plane. Lapping is distinct from grinding in that grinding uses a fixed abrasive, whereas lapping uses a slurry with particles (e.g., diamond) in suspension. Grinding and lapping are both intended as ‘material removal’ which distinguishes them from polishing, which is meant to knock down asperities/roughness rather than remove material. Grinding can do material removal with a smaller particle size than lapping, because in the latter, particles are fixed in a solid medium, and thus impart more force. For slurries, the border between polishing and lapping is at about 6-9 μm (for GaN and other hard crystals).

Dashed line 204 represents material removed from the wafer 200. The size of the removed material, as well as features of the first surface 202 and grinder 206 are not necessarily to scale and may be exaggerated for purpose of illustration. A grinding or lapping particle size of 30 μm can produce such a surface 202, though other particle sizes are also expected to produce such a surface 202. In addition to exposing a variety of planes, the lapping process leaves broken bonds and sub-surface damage that is deliberately left ‘uncured’ e.g., by a high temperature anneal or wet etch or dry etch process. Chemical mechanical planarization (CMP) was also considered as a means to form the surface 202.

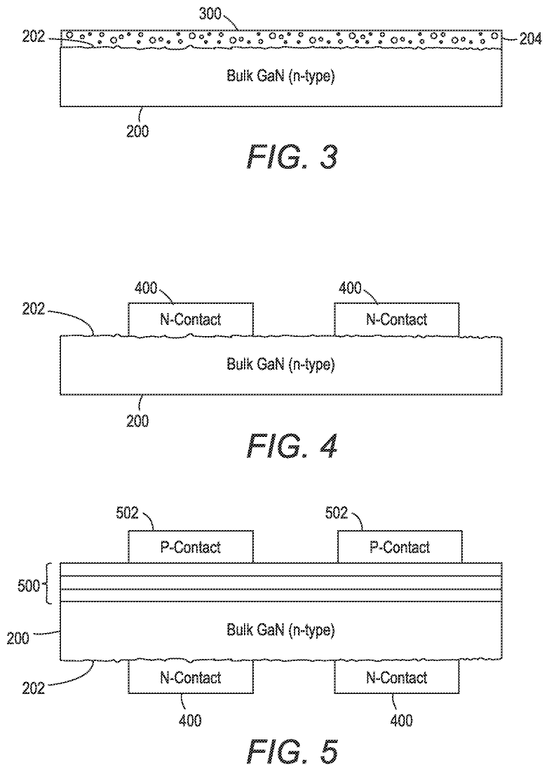

As seen in FIG. 3 surface treatment (typically wet chemical etch with etchant 300) is executed on the roughened surface 202. An etchant 300 that includes an HCl solution has been found to be most beneficial in most cases, but buffered oxide etch (BOE) or a combination of HCl and BOE, or even alternate chemistries such as KOH may yield better results as it appears there is a substrate/chemistry interaction.

As seen in FIG. 4 contact metal having low work function (e.g., Ti, Al, TiN, or others) is applied by conventional thin film deposition methods (e-beam, evaporative, or sputter deposition). The contact metal can be shaped by photolithographic patterning and etching to form negative electrical contacts 400 if desired. The electrical contacts 400 are not exposed to any anneal step at high temperature (e.g., >300 C) or exposed to an elevated temperature for long duration (e.g., >200 C for >1 min.).

As seen in FIG. 5, additional layers 500 are formed on a second surface 501 of the wafer 200 that faces away from the first surface 202. These layers 500 are often epitaxially grown, however non-crystalline materials may also be used to form the layers, e.g., dielectrics. Positive electrical contacts 502 are formed in contact with a top layer (e.g., a p-doped layer) of the additional layers 500. The bulk wafer material 200, additional layers 500, and electrical contacts 400, 402 form semiconductor devices 504. These devices 504 may remain together on a common substrate (e.g., as in a display) or be separated to form individual devices.

Note that the order of device formation may vary from what is shown in FIGS. 2-5. For example, the additional layers 500 (and possibly the positive electrical contacts 502) may be grown/deposited before roughening and treating the first surface 202 and subsequent forming of the negative electrical contacts 400. Such an ordering of process steps may be desirable or necessary, e.g., when formation of the additional layers 500 is performed at high temperatures.

A surface grinding process as described above may use a fixed abrasive, or other similar thinning process (e.g., lapping, wire sawing, dicing) that creates a surface characterized by multiple exposed planes as distinct from a smooth surface consisting exclusively or predominantly of the N (0001̅) face. A lapping/grinding particle size of 30 μm can produce such a surface, though other particle sizes are also expected to produce such a surface. In addition to exposing a variety of planes, the lapping process leaves broken bonds and sub-surface damage that is deliberately left ‘uncured’ e.g., by excluding subsequent high temperature anneal or other wet etch or dry etch process which removes damaged material or otherwise ameliorates broken bonds.

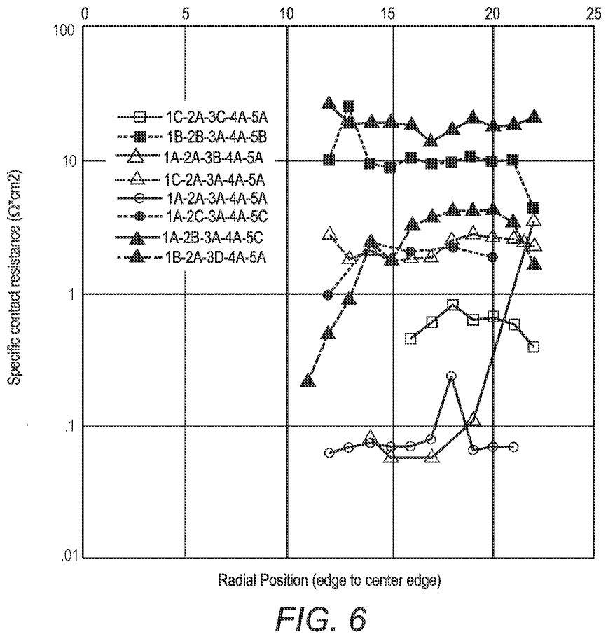

In FIG. 6, a graph shows experimental data gathered using different processing of bulk GaN wafer from three different vendors. Each plotted curve is coded with a series of alphanumeric designators that indicate the vendor and the different sequential processing steps that were applied before the measurements were taken. In Table 1 below, the meaning of each alphanumeric pair.

TABLE 1
Codes used in FIG. 5

| Code Segment/Step | Meaning |
|---|---|
| 1. Vendor | 1A - Vendor A; 1B - Vendor B; 1C - Vendor C |
| 2. Surface processing | 2A - Grind at 30 μm; 2B - Polish at 6 μm; |
| | 2C - CMP |
| 3. Pre contact deposition | 3A - BOE; 3B - HCl; 3C - KOH; 3D - No |
| treatment | surface treatment |
| 4. Contact metal | 4A - Ti |
| 5. Post-contact anneal | 5A - No anneal; 5B -200 C., 5 min.; 5C - |
| | 400 C., 1 min. |

Comparisons of contact resistance (directly related to final device forward voltage) show that the polishing process (using smaller particle size abrasives of 6 um and below) performs worst for all wafer types. Grind is superior in terms of contact resistance and CMP is also superior for some vendors, but the CMP process is significantly more costly to carry out. These results are prior to optimized surface treatment processes which further improve performance, lessening variation between wafer types.

Generally, what is optimal can vary, but based on these experiments, grinding at 30 um (Step 2) returns best in class results, as does low work function metal such as Ti (step 4), and the absence of anneal (Step 5). On the other hand, what is optimal for Step 3 (pre contact deposition surface treatment) can vary due to wafer vendor differences (e.g., doping strategy) and will benefit from individual optimization.

The improved performance may be explained by the presence of a multiplicity of planes beyond the (0001̅) N face, as well as the presence of surface and subsurface damage (broken bonds) and the resulting increase in electronic states.

Generally, an N face surface seems to benefit from the presence of a multitude of crystal planes of a rough surface, induced by mechanical processes having large abrasive particle size. Using a low work function as a contact metal in the roughened surface also benefits by reducing resistance in the resulting device. An optimized chemical surface treatment, such as HCl and/or BOE or other chemical treatment, may be determined through testing with specific vendor samples. By avoiding thermal cycling (e.g., anneal) after contact deposition, the resulting semiconductor device (e.g., transistor, diode, laser) will exhibit low resistance across the n-contact.

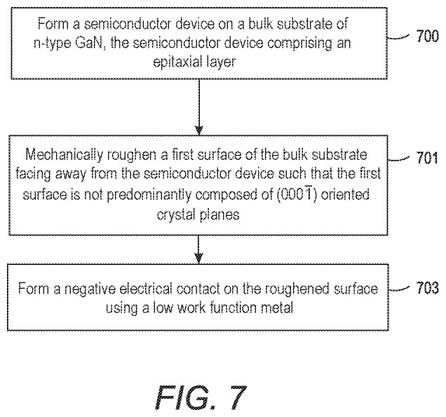

In FIG. 7, a flowchart shows a method according to an example embodiment. The method involves forming 700 a semiconductor device on a bulk substrate of n-type GaN. The semiconductor device comprises an epitaxial layer. A first surface of the bulk substrate facing away from the semiconductor device is mechanically roughened 701 such that the first surface is not predominantly composed of (0001̅) oriented crystal planes. A negative electrical contact is formed 702 on the roughened surface using a low work function metal.

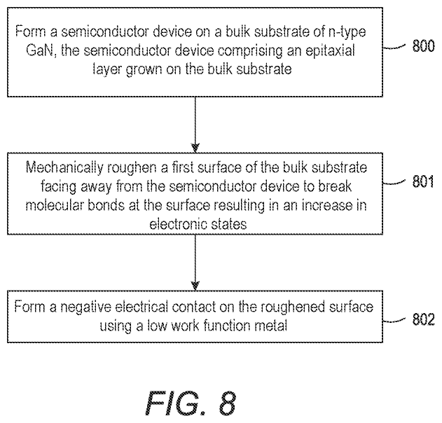

In FIG. 8, a flowchart shows a method according to an example embodiment. The method involves forming 800 a semiconductor device on a bulk substrate of n-type GaN. The semiconductor device includes an epitaxial layer grown on the bulk substrate. A first surface of the bulk substrate facing away from the semiconductor device is mechanically roughened 801 to break molecular bonds at the surface resulting in an increase in electronic states. A negative electrical contact is formed 802 on the roughened surface using a low work function metal. Note that in some embodiments, the forming 800 of the semiconductor device may occur after the roughening 801 and contact formation 802.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. The use of numerical ranges by endpoints includes all numbers within that range (e.g. 1 to 5 includes 1, 1.5, 2, 2.75, 3, 3.80, 4, and 5) and any range within that range.

The terms “coupled” or “connected” refer to elements being attached to each other either directly (in direct contact with each other) or indirectly (having one or more elements between and attaching the two elements). Either term may be modified by “operatively” and “operably,” which may be used interchangeably, to describe that the coupling or connection is configured to allow the components to interact to carry out at least some functionality.

Terms related to orientation, such as “top,” “bottom,” “side,” and “end,” are used to describe relative positions of components (e.g., as arranged in the figures) and are not meant to limit the orientation of the embodiments contemplated. For example, an embodiment described as having a “top” and “bottom” also encompasses embodiments thereof rotated in various directions unless the content clearly dictates otherwise.

Reference to “one embodiment,” “an embodiment,” “certain embodiments,” or “some embodiments,” etc., means that a particular feature, configuration, composition, or characteristic described in connection with the embodiment is included in at least one embodiment of the disclosure. Thus, the appearances of such phrases in various places throughout are not necessarily referring to the same embodiment of the disclosure. Furthermore, the particular features, configurations, compositions, or characteristics may be combined in any suitable manner in one or more embodiment.

References to a “combination” of different elements is also meant to include each element on its own unless otherwise indicated. For example, a combination of A, B, and C may include any one of A, B, or C alone, as well as A+B, A+C, A+B+C, etc. Further, where the elements of the combinations are actions (e.g., steps of a method), the listing of actions is not meant to imply a specific order that the actions may be taken in the combination unless otherwise indicated.

The foregoing description of the example embodiments has been presented for the purposes of illustration and description. It is not intended to be exhaustive or to limit the embodiments to the precise form disclosed. Many modifications and variations are possible in light of the above teaching. Any or all features of the disclosed embodiments can be applied individually or in any combination and are not meant to be limiting, but purely illustrative. It is intended that the scope of the invention be limited not with this detailed description, but rather determined by the claims appended hereto.

1. A method, comprising:
forming a semiconductor device on a bulk substrate of n-type GaN, the semiconductor device comprising an epitaxial layer;
mechanically roughening a first surface of the bulk substrate facing away from the semiconductor device such that the first surface is not predominantly composed of (0001̅) oriented crystal planes; and
forming a negative electrical contact on the roughened surface using a low work function metal.

2. The method of claim 1, wherein the mechanically roughening of the first surface comprises wafer grinding or lapping the surface.

3. The method of claim 2, wherein the wafer grinding or lapping uses a particle size of 6 μm or more.

4. The method of claim 1, wherein the mechanically roughening of the first surface comprises wire sawing or dicing the bulk substrate.

5. The method of claim 1, wherein after forming the negative electrical contact, the negative electrical contact is not exposed to any anneal of >300° C. or an anneal of more than one minute at >200° C.

6. The method of claim 1, further comprising chemically treating the first surface using a wet etch chemical before forming the negative electrical contact.

7. The method of claim 6, wherein the wet etch chemical comprises any combination of HCl and HF containing a buffered oxide etch.

8. The method of claim 1, wherein the low work function metal comprises at least one of Ti, Al, or TiN.

9. The method of claim 1, wherein the mechanical roughening of the first surface of the bulk substrate results in broken molecular bonds at the first surface resulting in an increase in electronic states.

10. The method of claim 1, wherein the epitaxial layer comprises a p-type epitaxial layer, the method further comprising forming a positive electrical contact on the p-type epitaxial layer.

11. A method, comprising:
forming a semiconductor device on a bulk substrate of n-type GaN, the semiconductor device comprising an epitaxial layer grown on the bulk substrate;
mechanically roughening a first surface of the bulk substrate facing away from the semiconductor device to break molecular bonds at the surface resulting in an increase in electronic states; and
forming a negative electrical contact on the roughened surface using a low work function metal.

12. The method of claim 11, wherein the mechanically roughening of the first surface comprises wafer grinding or lapping the first surface.

13. The method of claim 12, wherein the wafer grinding or lapping uses a particle size of 6 μm or more.

14. The method of claim 11, wherein the mechanically roughening of the first surface comprises wire sawing or dicing the bulk substrate.

15. The method of claim 11, wherein after forming the negative electrical contact, the negative electrical contact is not exposed to any anneal of >300° C. or an anneal of more than one minute at >200° C.

16. The method of claim 11, further comprising chemically treating the roughened surface using a wet etch chemical before forming the bottom electrical contact.

17. The method of claim 16, wherein the wet etch chemical comprises any combination of HCl and HF containing a buffered oxide etch.

18. The method of claim 11, wherein the low work function metal comprises at least one of Ti, Al, or TiN.

19. The method of claim 11, wherein the mechanical roughening of the surface of the bulk substrate results in the surface not being predominantly composed of (0001̅) oriented crystal structures.

20. The method of claim 11, wherein epitaxial layer comprises a p-type epitaxial layer, the method further comprising forming a positive electrical contact on the p-type epitaxial layer.
